(19) United States
(12) Patent Application Publication
(10) Pub. No.: US 2015/0204929 A1
(43) Pub. Date: Jul. 23, 2015

(54) TESTING SYSTEM AND METHOD OF INSTANT INFORMING WITH THE SAME

(71) Applicant: MPI CORPORATION, ZHUBEI (TW)

(72) Inventors: WEI-CHENG KU, ZHUBEI (TW); SHOA-WEI LU, ZHUBEI (TW); YU-TSE WANG, ZHUBEI (TW)

(73) Assignee: MPI CORPORATION, ZHUBEI (TW)

(21) Appl. No.: 14/557,311

(22) Filed: Dec. 1, 2014

(30) Foreign Application Priority Data
Dec. 13, 2013 (TW) 102146084

(51) Int. Cl. G01R 31/00; H04B 17/29

(52) U.S. Cl. CPC G01R 31/00; H04B 17/29

(57) ABSTRACT

A testing system includes a test machine, a communication device, a server, and a user-end device. The test machine does electrical test on an electronic product, wherein the test machine generates a first signal when the test is completed, and generates a second signal when the measured yield is lower than a predetermined threshold. The communication device is electrically connected to the test machine to receive the first signal or the second signal. The communication device correspondingly converts the received signals into first information or second information, and then outputs the first and the second information to a first network. The server communicates with the first network to receive the first and the second information outputted by the communication device, and then outputs the received information to a second network. The user-end device communicates with the second network to receive the first and the second information outputted by the server.

### BACKGROUND OF THE INVENTION

1. Technical Field

The present invention relates generally to a testing system, and more particularly to a testing system which is capable of instantly informing a tester, and a testing system of instant informing with the testing system.

2. Description of Related Art

To ensure the quality of electronic products, manufacturers commonly use a testing system to check electrical connections between each precision electronic component in different stages of the manufacturing process.

To ensure the testing process runs smoothly, there is typically a tester assigned at a testing system. In this way, once the yield appears to be too low, or the testing system malfunctions, the tester can promptly handle the situation.

However, since generally a testing system can work normally in most of the time, assigning a tester at the testing system to deal with rare conditions seems to be a waste of human resource.

### BRIEF SUMMARY OF THE INVENTION

In view of the above, the primary objective of the present invention is to provide a testing system, which is capable of instantly providing information about completion of the test, low yield, or malfunction of the test machine to a tester through wireless communication.

The present invention provides a testing system, which includes a test machine, a communication device, a server, and at least one user-end device. The test machine does an electrical test on an electronic product, wherein the test machine generates a first signal when the electrical test is completed, and generates a second signal when measured yield of the electronic product is lower than a predetermined threshold. The communication device is electrically connected to the test machine to receive the first signal and the second signal, wherein the communication device communicates with a first network, and correspondingly converts the received first and second signals into first information and second information to be outputted to the first network. The server communicates with the first network and a second network, wherein the server receives the first and the second information outputted to the first network by the communication device, and outputs the received first and second information to the second network. The at least one user-end device communicates with the second network to receive the first and the second information outputted to the second network by the server.

The present invention further provides a testing system of instant informing with a testing system which does an electrical test on an electronic product. The testing system includes the following steps: (a) generate a first signal or a second signal, wherein the first signal is generated when the electrical test is completed, and the second signal is generated when measured yield of the electronic product is lower than a predetermined threshold; (b) receive the first signal or the second signal, and correspondingly convert the received first or second signal into first information or second information to be outputted to a first network; (c) receive the first information or the second information outputted to the first network, and then output the received first or second information to a second network; and (d) receive the first information or the second information outputted to the second network with at least one user-end device.

With the aforementioned design, a tester can be instantly informed that a test is completed, the yield is too low, or the test machine malfunctions through wireless communication.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic diagram of the testing system in a preferred embodiment of the present invention; and

FIG. 2 is a flow chart of the testing system of instant informing in a preferred embodiment of the present invention.

### DETAILED DESCRIPTION OF THE INVENTION

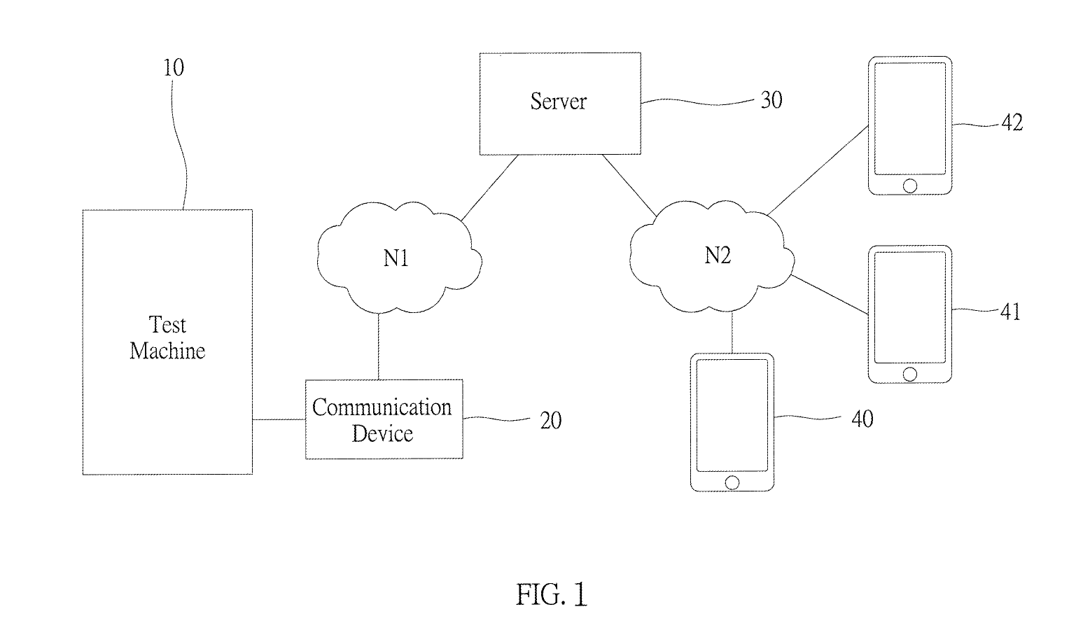

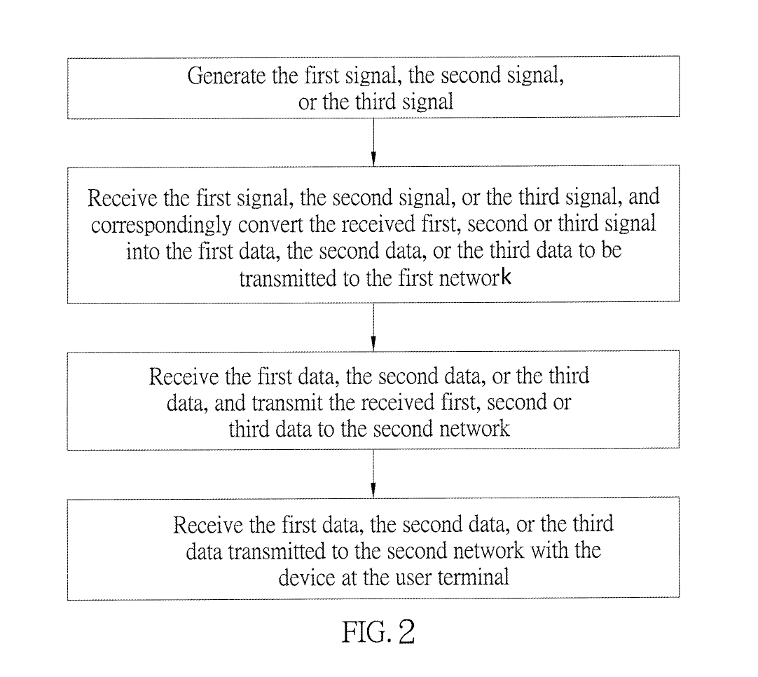

As shown in FIG. 1 and FIG. 2, a testing system of the preferred embodiment of the present invention includes a test machine 10, a communication device 20, a server 30, and a plurality of user-end devices 40-42.

The test machine 10 is used to do electrical tests on an electronic product (i.e., wafer, chip, circuit board, etc.). The test machine 10 is provided with a monitor circuit (not shown), which generates a first signal when the test machine 10 completes the test, generates a second signal when the measured yield of the electronic product is lower than a predetermined threshold, and generates a third signal when the test machine 10 malfunctions. In addition, upon generating the first signal, data obtained during the test can be also attached to the first signal by the monitor circuit.

The communication device 20 is electrically connected to the monitor circuit of the test machine 10 to receive the first to the third signals generated and outputted by the monitor circuit. In addition, the communication device 20 communicates with a first network N1. The communication device 20 correspondingly converts the received first to third signals into first information, second information, and third information, and then output the first to the third information to the first network N1. For example, these pieces of information can be textual information such as, respectively, “test completed”, “yield too low”, or “machine malfunction”. In the preferred embodiment, the first network N1 is Internet.

The server 30 communicates with the first network N1 to receive the first to the third information which is outputted to the first network N1 by the communication device 20. On the other hand, the server 30 also communicates with a second network N2, wherein the server 30 transfers the received first to third information to the second network N2. In the preferred embodiment, the second network N2 is telecommunication network, and the server 30 outputs the first to the third information to the second network N2 through short message service (SMS).

In the preferred embodiment, the user-end devices 40-42 are cellphones which communicate with the second network N2, to receive the first to the third information outputted to the second network N2 by the server 30.

In this way, there is no need to assign a tester at the test machine 10 while it is operating. Instead, the tester can still do other work such as patrolling the factory or preparing materials, and only returns to the test machine 10 for replacing materials, removing materials, or troubleshooting when the user-end device 40 carried by the tester receives any piece of the first to the third information, which improves the tester's work efficiency.

It is worth mentioning that the communication device 20 can further has a communication list provided in software thereof, which lists addresses or phone numbers corresponding to the user-end devices 40-42. With the communication list, it is possible to inform different testers when the test machine 10 encounters different conditions. For example, the user-end devices 40-42 are, respectively, a first user-end device 40, a second user-end device 41, and a third user-end device 42; when the communication device 20 receives the first signal, the second signal, or the third signal outputted by the monitor circuit of the test machine 10, and correspondingly converts the received signal into the first information, the second information, or the third information, the address or phone number of the first user-end device 40, the second user-end device 41, or the third user-end device 42 are attached along with the information, therefore the server 30 is able to transmit the first information, the second information, and the third information to the corresponding user-end device 40-42 through the second network N2 according to the attached address or phone number.

In other words, if the communication device 20 is set in advance to inform the first user-end device 40 when the test machine 10 completes the test, to inform the second user-end device 41 when the measured yield is lower than the predetermined threshold, and to inform the third user-end device 42 when test machine 10 malfunctions, then, once the test machine 10 encounters the above conditions, the first user-end device 40 receives the first information, the second user-end device 41 receives the second information, the third user-end device 42 receives the third information. As a result, different testers or maintenance workers can be informed of different conditions.

In addition, the server 30 provided in the present invention is not only compatible with the first network N1 as Internet and the second network N2 as telecommunication network, but also compatible with the first network N1 as telecommunication network and the second network N2 as Internet. In other embodiments, the first network N1 and the second network N2 can be both Internet or telecommunication network at the same time, and the server 30 can still compatible with such network environment.

Furthermore, under the condition that the second network N2 is telecommunication network, in addition to transmitting the first to the third information through SMS as described above, the server 30 can also use voice messages to make the user-end devices 40-42 receive the first to the third information. Moreover, under the condition that the second network N2 is Internet, the first to the third information can be transmitted via e-mail by the server 30, which is convenient for a tester to check and save the data attached to the first signal.

In addition, the user-end devices 40-42 can be laptops, PDAs, tablet computers in other embodiments, as long as the user-end devices are capable of connecting network.

The embodiment described above is only a preferred embodiment of the present invention. All equivalent constructions and methods which employ the concepts disclosed in this specification and the appended claims should fall within the scope of the present invention.

What is claimed is:

1. A testing system, comprising:
a test machine, which does an electrical test on an electronic product, wherein the test machine generates a first signal when the electrical test is completed, and generates a second signal when measured yield of the electronic product is lower than a predetermined threshold;
a communication device electrically connected to the test machine to receive the first signal and the second signal, wherein the communication device communicates with a first network, and correspondingly converts the received first and second signals into first information and second information to be outputted to the first network;
a server which communicates with the first network and a second network, wherein the server receives the first and the second information outputted to the first network by the communication device, and outputs the received first and second information to the second network; and
at least one user-end device, which communicates with the second network to receive the first and the second information outputted to the second network by the server.

2. The testing system of claim 1, wherein the at least one user-end device includes two user-end devices, which are, respectively a first user-end device and a second user-end device; the first information and the second information outputted by the communication device is respectively attached with addresses or phone numbers of the first user-end device and the second user-end device, which makes the first user-end device receive the first information, and the second user-end device receive the second information.

3. The testing system of claim 1, wherein when the test machine malfunctions, a third signal is generated and outputted to the communication device; the communication device converts the received third signal into corresponding third information to be outputted to the first network; the server receives the third information, and then outputs the received third information to the at least one user-end device though the second network.

4. The testing system of claim 3, wherein the at least one user-end device includes three user-end devices, which are, respectively, a first user-end device, a second user-end device, and a third user-end device; the first information, the second information, and the third information outputted by the communication device is respectively attached with addresses or phone numbers of the first user-end device, the second user-end device, and the third user-end device, which makes the first user-end device receive the first information, the second user-end device receive the second information, and the third user-end device receive the third information.

5. A method of instant informing with a testing system which does an electrical test on an electronic product, comprising the steps of:
(a) generating a first signal or a second signal, wherein the first signal is generated when the electrical test is completed, and the second signal is generated when measured yield of the electronic product is lower than a predetermined threshold;
(b) receiving the first signal or the second signal, and correspondingly converting the received first or second signal into first information or second information to be outputted to a first network;
(c) receiving the first information or the second information outputted to the first network, and then outputting the received first or second information to a second network; and
(d) receiving the first information or the second information outputted to the second network with at least one user-end device.

6. The method of claim 5, wherein the at least one user-end device includes two user-end devices, which are, respectively, a first user-end device and a second user-end device; addresses or phone numbers of the first user-end device and the second user-end device are respectively attached to the first information and the second information in step (b); whereby the first information is received by the first user-end device, and the second information is received by the second user-end device in step (d).

7. The method of claim 5, wherein a third signal is further generated in step (a) when the testing system malfunctions; the third signal is received and converted into third information to be outputted to the first network in step (b); the third information is received and outputted to the second network in step (c); the third information is received by the at least one user-end device in step (d).

8. The method of claim 7, wherein the at least one user-end device includes three user-end devices, which are, respectively, a first user-end device, a second user-end device, and a third user-end device; addresses or phone numbers of the first user-end device, the second user-end device, and the third user-end device are respectively attached to the first information, the second information, and the third information in step (b); whereby the first information is received by the first user-end device, the second information is received by the second user-end device, and the third information is received by the third user-end device in step (d).

9. The method of claim 5, wherein the first network and the second network are both Internet.

10. The method of claim 9, wherein the at least one user-end device receives the first information or the second information which is outputted to the second network via email in step (d).

11. The method of claim 5, the first network and the second network are both telecommunication network.

12. The method of claim 11, wherein the at least one user-end device receives the first information or the second information which is outputted to the second network via short message service in step (d).

13. The method of claim 11, wherein the at least one user-end device receives the first information or the second information which is outputted to the second network through a voice message in step (d).

14. The method of claim 5, wherein the first network is Internet, and the second network is telecommunication network.

15. The method of claim 14, wherein the at least one user-end device receives the first information or the second information which is outputted to the second network via email in step (d).

16. The method of claim 5, wherein the first network is telecommunication network, and the first network is Internet.

17. The method of claim 16, wherein the at least one user-end device receives the first information or the second information which is outputted to the second network via short message service in step (d).

18. The method of claim 16, wherein the at least one user-end device receives the first information or the second information which is outputted to the second network through a voice message in step (d).
